(19) United States
(12) Patent Application Publication
(10) Pub. No.: US 2026/0255486 A1
(43) Pub. Date: Aug. 27, 2026

(54) Vertical Cage Daughterboard for Vertical Pluggable Modules

(71) Applicant: Ciena Corporation, Hanover, MD (US)

(72) Inventors: Daniel Rivaud, Ottawa (CA); Fabien Colton, Kars (CA); Roger Paul Toutant, Vernon (CA); Lloyd Nelson Cosman, Stittsville (CA)

(73) Assignee: Ciena Corporation, Hanover, MD (US)

(21) Appl. No.: 19/061,013

(22) Filed: Feb. 24, 2025

(51) Int. Cl. H05K 1/14; H05K 1/02

(52) U.S. Cl. CPC H05K 1/141; H05K 1/0203; H05K 1/144; H05K 2201/045; H05K 2201/066; H05K 2201/10189; H05K 2201/10212

(57) ABSTRACT

A vertical line card (VLC) arrangement for networking modules is disclosed. The system includes a mainboard containing a high-speed ASIC and one or more outward cage structures, along with a centrally located daughterboard supporting one or more additional cages. This architecture significantly shortens high-speed SerDes traces, preserves front-to-back airflow, and sustains high port density. By mounting certain cages directly on the mainboard, extra insertion losses from interconnects are eliminated, while the centrally positioned daughterboard ensures only minimal additional signal degradation. Strategic cutouts and angled faceplates provide optimal thermal management. Overall, the solution avoids expensive flyover cables or multiple board-to-board connectors and accommodates busbar power delivery for high-current ASICs. This modular design offers flexibility in port counts, component placement, and power management, enabling robust signal integrity and enhanced heat dissipation for next-generation data center and telecom systems.

### FIELD OF THE DISCLOSURE

The present disclosure relates generally to networking hardware. More particularly, the present disclosure relates to a vertical cage daughterboard hardware implementation for vertical pluggable modules.

### BACKGROUND OF THE DISCLOSURE

In traditional designs of networking and computing hardware, octal small form factor pluggable (OSFP) cage connectors are mounted at a right angle to the plane of a printed circuit board (PCB), leading to comparatively long routing traces and constrained airflow. A vertical line card (VLC) introduces a new configuration by mounting the OSFP cage connector perpendicularly to the PCB, thereby reducing the overall length of high-speed SerDes (serializer-deserializer) signal traces and improving signal integrity at ever-increasing data rates. A key feature of the VLC design is a strategically placed hole in the PCB that allows front-to-back airflow, which helps dissipate heat generated by high-power optical or electrical modules. By aligning the transceiver vertically and shortening the signal path between the connector and onboard components, the VLC architecture minimizes insertion loss and crosstalk, an increasingly critical factor as bandwidth requirements escalate. In addition to improved thermal performance, this vertical arrangement affords greater flexibility in component placement and routing, ultimately providing a more efficient and scalable solution for next-generation data center and telecom applications.

### BRIEF SUMMARY OF THE DISCLOSURE

The present disclosure relates to a vertical cage daughterboard hardware implementation for vertically pluggable modules, such as a VLC (Vertical Line Card) for OSFP cages, although other types of modules and cages are also contemplated, including both optical or electrical modules. OSFP is a pluggable optical module specification designed to support data rates of 400 Gbps and beyond by incorporating eight high-speed electrical lanes. However, implementing a VLC approach for OSFP introduces certain challenges, particularly when attempting to locate OSFP cages directly over large central switching application-specific integrated circuits (ASICs), which may house hundreds or even thousands of SerDes lanes. Placing VLC cages directly adjacent to these large ASICs on a PCB is typically infeasible due to mechanical, thermal, and electrical constraints. As a result, designers are forced to shift the cages away from the ASIC, which increases trace lengths, reduces overall port density, and exacerbates signal integrity issues as SerDes rates continue to increase. Moreover, reducing port density directly undermines one of the principal objectives of a high-density networking system.

By way of example, in developing a high-density router switching matrix around a central switching ASIC that provides 1024 SerDes lanes and supports 128 OSFP ports, conventional approaches often require leaving the central portion of the VLC open to accommodate the ASIC while positioning the cages on the periphery. Although this preserves space for the ASIC, it simultaneously reduces the usable front-panel area (i.e., faceplate density) for additional ports. Another workaround involves employing flyover cables between the cages and the ASIC, but this solution is expensive, adds manufacturing complexity, and does not fully address the need for short, direct signal paths. Yet another approach involves placing the VLCs and the ASICs on entirely separate PCBs, which may resolve some front-panel density concerns but necessitates multiple board-to-board connectors, increasing signal loss and cost, particularly for OSFP modules that must be routed over a significant distance.

To overcome these limitations, the present disclosure proposes an enhanced vertical cage daughterboard solution that optimizes cage placement, manages trace lengths, and preserves overall density for next-generation high-speed networking systems. More specifically, this arrangement includes: (i) a central PCB (“mainboard”) that houses the high-speed switching ASIC and also integrates OSFP cages at its outward edges, and (ii) a daughterboard that supports the central VLC cages. The mainboard contains the ASIC and the OSFP cages located on the far left and right edges, those that are inherently the farthest from the ASIC, so these ports avoid extra insertion losses associated with additional connectors as the traces are on the mainboard. The central cages, which are physically closer to the ASIC, reside on the daughterboard, where the modest (~0.5 dB) penalty due to the daughterboard connector is tolerable given their shortened trace lengths. This hybrid configuration maintains the desired faceplate density, confines longer traces to the mainboard for improved signal integrity, and remains more cost-effective and reliable than alternatives such as flyover cables or fully separate PCBs for cages and ASICs.

In an embodiment, a vertical line card includes a main printed circuit board having at least one high-speed switching integrated circuit disposed thereon; one or more cage structures mounted on the main printed circuit board, each cage structure including a plurality of vertically oriented module cages; a daughterboard; and at least one cage structure mounted on the daughterboard, the at least one cage structure including a plurality of vertically oriented module cages. Signal traces between the high-speed switching integrated circuit and the at least one cage structure are shorter than signal traces between the high-speed switching integrated circuit and the one or more cage structures, thereby reducing insertion loss at high data rates. The high-speed switching integrated circuit can include a signal processing circuit capable of multiple terabits per second of switching capacity.

Each of the one or more cage structures and the at least one cage structure can be configured to accept one or more of octal small form factor pluggable (OSFP) modules, C-form factor pluggable (CFP) modules, or quad small form factor pluggable (QSFP) modules. The vertical line card can include at least one hole or cutout in the main printed circuit board configured to facilitate front-to-back airflow through the vertically oriented module cages. The vertical line card can include a power distribution system including at least one busbar or vertical power-delivery structure configured to supply current to the high-speed switching integrated circuit.

The vertical line card can include one or more mezzanine connectors configured to couple the daughterboard to the main printed circuit board. The daughterboard can be positioned between the one or more cage structures which include a first cage structure and a second cage structure, and the one or more mezzanine connectors are located to optimize signal integrity and airflow to a heatsink associated with the high-speed switching integrated circuit. The at least one cage structure can protrude outward from a plane defined by the one or more cage structures to accommodate higher faceplate density within a limited chassis height. The at least one cage structure can be a single structure having more cages than the one or more cage structures. The at least one cage structure can include a plurality of cage structures, where the plurality of cage structures are each on the daughterboard.

In another embodiment, a network element includes a housing; and a vertical line card disposed within the housing, the vertical line card includes a main printed circuit board having at least one high-speed switching integrated circuit disposed thereon; one or more cage structures mounted on the main printed circuit board, each cage structure including a plurality of vertically oriented module cages; a daughterboard; and at least one cage structure mounted on the daughterboard, the at least one structure including a plurality of vertically oriented module cages. Signal traces between the high-speed switching integrated circuit and the at least one cage structure are shorter than signal traces between the high-speed switching integrated circuit and the one or more structures, thereby reducing insertion loss at high data rates. The high-speed switching integrated circuit can include a signal processing circuit capable of multiple terabits per second of switching capacity.

Each of the one or more cage structures and the at least one cage structure can be configured to accept one or more of octal small form factor pluggable (OSFP) modules, C-form factor pluggable (CFP) modules, or quad small form factor pluggable (QSFP) modules. The network element can include a cooling system arranged to provide front-to-back airflow through the housing, wherein the vertical line card includes at least one hole or cutout in the main printed circuit board configured to facilitate front-to-back airflow through the vertically oriented module cages. The network element can include a power supply arranged to provide current to the vertical line card, wherein the vertical line card includes at least one busbar or vertical power-delivery structure configured to supply current to the high-speed switching integrated circuit. The vertical line card can include one or more mezzanine connectors that couple the daughterboard to the main printed circuit board. The at least one cage structure can be a single structure having more cages than the one or more cage structures. The at least one cage structure can include a plurality of cage structures, where the plurality of cage structures are each on the daughterboard.

### BRIEF DESCRIPTION OF THE DRAWINGS

The present disclosure is detailed through various drawings, where like components or steps are indicated by identical reference numbers for clarity and consistency.

FIG. 1 illustrates a perspective diagram of a VLC, including a printed circuit board (PCB) and three cage structures arranged along a first side of the PCB.

FIG. 2 illustrates a VLC providing a partial solution by allocating space for a high-speed, high-powered ASIC on the first side of the PCB, specifically, by omitting one of the cage structures to make room.

FIG. 3 illustrates another alternative, designated VLC, in which the high-speed, high-powered ASIC (not shown) is mounted on a second PCB located adjacent to the first PCB.

FIGS. 4 and 5 illustrate perspective diagrams of a VLC that addresses the faceplate density shortfall observed in FIG. 2 and avoids the longer trace lengths and additional connectors required in FIG. 3.

FIG. 6 illustrates a front view of the VLC of FIGS. 4 and 5 showing the cage openings in the cage structures.

FIG. 7 illustrates a side view of the VLC of FIGS. 4 and 5 and a rear view of the second side of the PCB with the ASIC.

FIGS. 8 – 12 illustrate various views of another example VLC as an alternate configuration with less cages in center cage structures, relative to the VLC of FIGS. 4 – 7.

FIGS. 13 and 14 illustrate front views of VLC of FIGS. 8 – 12 and the VLC of FIGS. 4 – 7, respectively, highlighting how the mezzanine connectors are positioned to electrically and mechanically couple the PCB 12 mainboard) with the daughterboard.

FIGS. 15 – 19 illustrate various views of a network element using the VLC of FIGS. 4 – 7.

### DETAILED DESCRIPTION OF THE DISCLOSURE

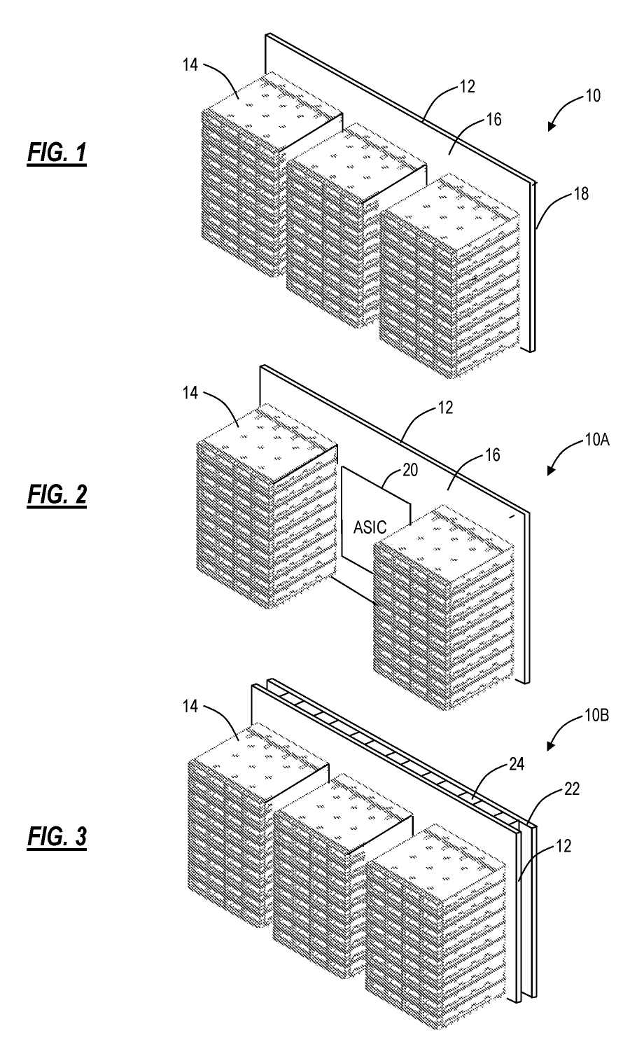

FIG. 1 illustrates a perspective diagram of a VLC 10, including a printed circuit board (PCB) 12 and three cage structures 14 arranged along a first side 16 of the PCB 12. Each cage structure 14 is composed of multiple rows and columns of individual cages, such as OSFP cages or the like, and in the illustrated example, there are thirty-six cages arranged as four columns by nine rows. Of course, different numbers of rows and columns, as well as different types of pluggable cages besides OSFP, are contemplated based on design requirements, such as, e.g., C-form factor pluggable (CFP), quad small form factor pluggable (QSFP), and the like. As known in the art, an OSFP cage is configured to accept an OSFP pluggable module, and the like. Unlike traditional right-angle mounting, the cage structures 14 in the VLC 10 employ connectors that mount perpendicularly to the plane of the PCB 12, thereby shortening high-speed SerDes trace lengths. Shorter trace lengths are critical for maintaining signal integrity and reducing insertion loss as SerDes rates scale to 400 Gbps and beyond. Additionally, the PCB 12 may include strategically placed holes (not shown) to facilitate front-to-back airflow through the aligned cages, thereby improving thermal management for high-power modules.

One key objective of the VLC 10 is to increase faceplate density by populating the majority of the first side 16 of the PCB 12 with cages, enabling the integration of numerous high-speed ports within a limited rack unit (RU) height. However, as shown in FIG. 1, a significant challenge arises in attempting to mount high-speed, high-powered ASICs (not shown) in conjunction with these cages. First, there is limited real estate on the first side 16 due to the extensive cage coverage. Second, mechanical constraints, such as the need for heatsinks and keep-out zones, prevent effective placement of a large ASIC on the same side. Third, thermal constraints dictate that the ASIC requires dedicated cooling paths, which may conflict with the vertical airflow needed for the cages. Finally, electrical considerations, including BGA ball fields, power delivery components, and escape routing, complicate placing an ASIC on an opposite (second) side 18. Hence, while FIG. 1 demonstrates how the VLC 10 achieves high cage density and reduced trace lengths to each cage, these conditions make it difficult to integrate large, high-power switching ASICs on either side of the PCB 12.

FIG. 2 illustrates a VLC 10A providing a partial solution by allocating space for a high-speed, high-powered ASIC 20 on the first side 16 of the PCB 12, specifically, by omitting one of the cage structures 14 to make room. This arrangement maintains relatively short routing distances between the remaining two cage structures 14 and the ASIC 20, thereby preserving many of the signal integrity benefits of a VLC. However, removing an entire cage structure 14 reduces the available front-panel area, significantly lowering the number of OSFP cages that can be supported. In high-density designs, such as those requiring 128 OSFP ports within a 5-RU network element, sacrificing an entire cage structure 14 makes it impossible to meet port-count targets. Thus, although FIG. 2 ensures short traces on a single PCB 12, the trade-off in port density is unacceptable for applications that demand both high port counts and high-speed performance.

FIG. 3 illustrates another alternative, designated VLC 10B, in which the high-speed, high-powered ASIC 20 (not shown) is mounted on a second PCB 22 located adjacent to the first PCB 12. In this approach, multiple board-to-board connectors 24 couple signals between the two PCBs 12, 22. While this permits the first PCB 12 to retain its full array of cages, thereby achieving the high faceplate density lacking in FIG. 2, it introduces additional signal loss and potential reflections at each connector interface. These effects partially undermine the principal objective of reducing trace lengths and insertion loss, especially for very high data rates. Moreover, board-to-board connectivity adds complexity to manufacturing, testing, and mechanical integration. Thus, although FIG. 3 preserves the maximum number of cage positions on the faceplate, the extra interconnect layers and signal impairments represent a significant drawback for designers striving to balance high port density, excellent signal integrity, and manageable system costs.

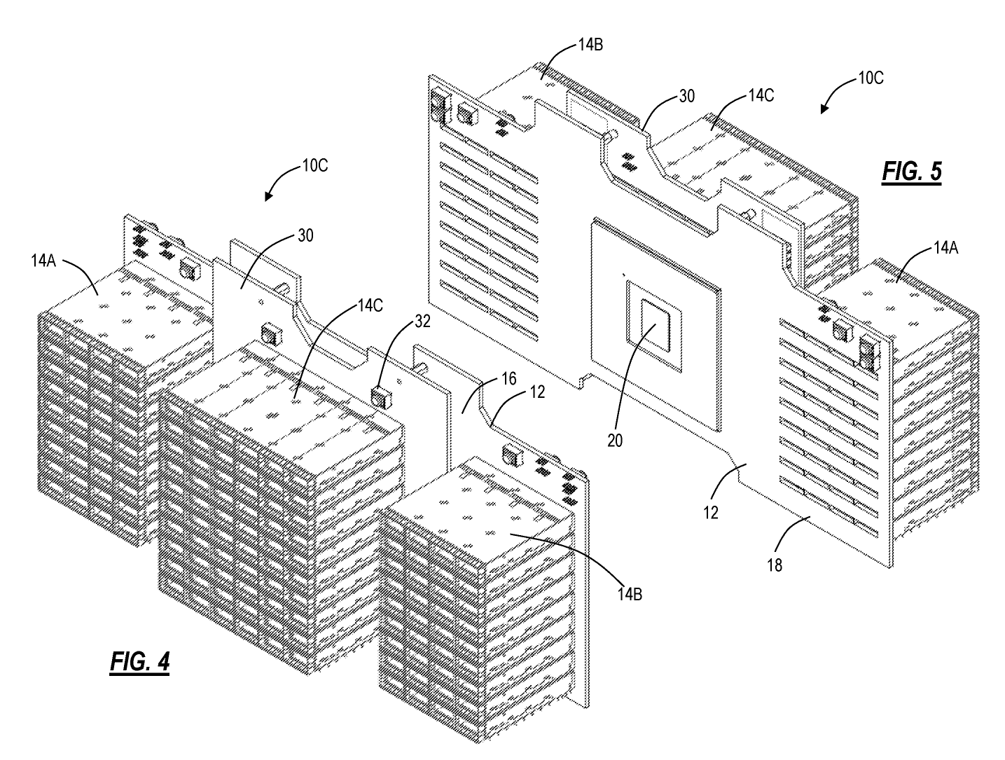

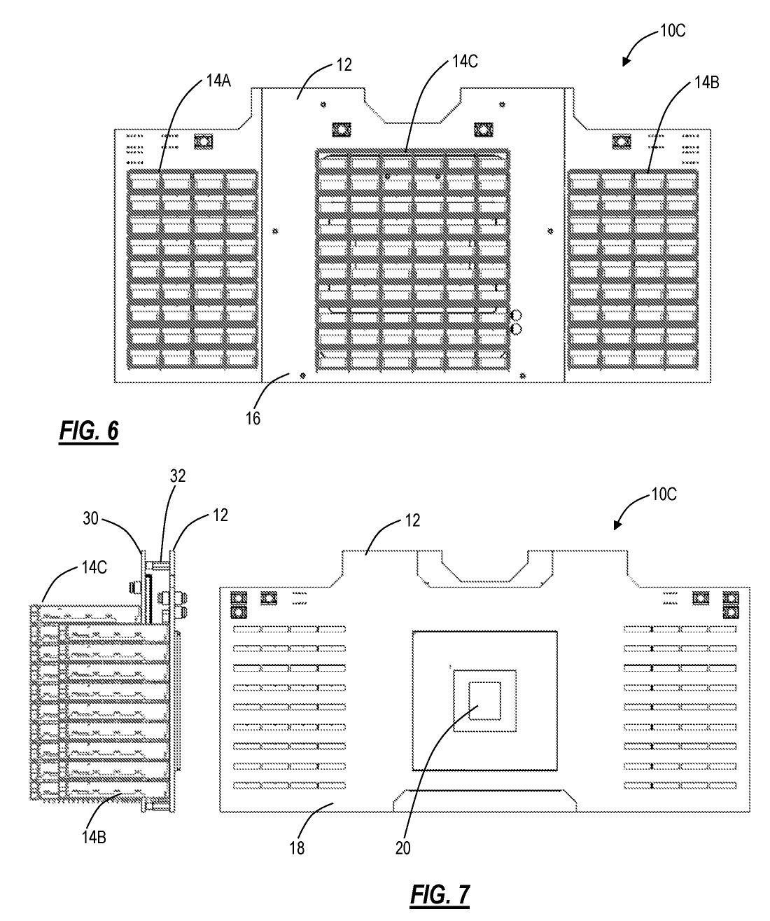

FIGS. 4 and 5 are perspective diagrams illustrating a VLC 10C that addresses the faceplate density shortfall observed in FIG. 2 and avoids the longer trace lengths and additional connectors required in FIG. 3. FIG. 4 provides a front-angled perspective of the VLC 10C, while FIG. 5 shows a rear-angled perspective of the same assembly. FIG. 6 illustrates a front view of the VLC 10C showing the cage openings in the cage structures 14A, 14B, 14C. FIG. 7 illustrates a side view of the VLC 10C and a rear view of the second side 18 of the PCB 12 with the ASIC 20. Note, in the side view of FIG. 7, the cage structure 14A is hidden from view. Together, these views highlight an enhanced vertical cage daughterboard solution that optimizes port placement, manages PCB routing distances, and preserves overall faceplate density for high-speed networking systems.

In this embodiment, the VLC 10C includes: (i) a central PCB 12 (the “mainboard”) that houses the high-speed switching ASIC 20 and also integrates two cage structures, 14A, 14B, on its outer edges; and (ii) a smaller daughterboard 30, on which a central cage structure 14C is mounted. The mainboard 12 is centrally located and features a footprint large enough to support both the daughterboard 30 with the ASIC 20 and the outer cage structures 14A, 14B. Since these outer cages lie farthest from the ASIC 20, they can be routed directly on the mainboard 12 without incurring additional insertion loss from extra connectors. Conversely, the cage structure 14C resides on the daughterboard 30, which physically attaches to the mainboard 12 via connectors 32. Because these central cages in the cage structure 14C are placed closer to the ASIC 20, they can tolerate the modest (~0.5 dB) insertion loss introduced by the daughterboard connector 32, thanks to their inherently shorter trace lengths.

In FIG. 4, the daughterboard 30 is shown positioned between the two outward cage structures 14A, 14B, with openings or cutouts shaped to accommodate both mechanical fasteners and airflow considerations. Each cage structure 14A, 14B, 14C is composed of multiple columns and rows of individual OSFP cages, thereby achieving the high faceplate density desired for next-generation network elements. FIG. 5, from an opposing perspective, reveals more detail of how the daughterboard 30 interfaces with the mainboard 12. As shown, the ASIC 20 is prominently mounted on the daughterboard 30, with sufficient space allocated for required heatsinks or other thermal management solutions. The connectors 32 coupling the daughterboard 30 to the mainboard 12 are strategically located to minimize both signal path lengths and mechanical stress, while also allowing convenient assembly and service access.

This hybrid configuration shown in FIGS. 4 and 5 proves more economical and reliable than approaches involving flyover cables or completely separate PCBs for cages and ASICs 20. The design maintains short trace lengths for both the outer cages in the cage structures 14A, 14B and the central cages in the cage structure 14C, ensuring robust signal integrity at multi-hundred gigabit data rates. Moreover, it achieves the high port density required in advanced data center and telecom applications, demonstrating how a well-planned distribution of cages between a mainboard and a daughterboard can resolve thermal, mechanical, and electrical challenges without sacrificing performance or density.

In this illustrative example, the VLC 10C features two outward cage structures 14A, 14B, each configured with four columns of nine rows for a total of thirty-six OSFP cages per structure, adding up to seventy-two cages between them. Centrally mounted on the daughterboard 30 is the third cage structure 14C, which provides an additional six columns of ten rows, bringing the total to sixty cages. Altogether, the three cage structures 14A, 14B, 14C in the VLC 10C support 132 cages in a unified assembly. By offering this high port density—sufficient for large-scale implementations such as 128 or more optical transceiver ports—the VLC 10C design is well-suited for a 5 RU (rack unit) module, chassis, or shelf commonly employed in data center or telecom infrastructure. Of course, the specific configuration of rows and columns is merely illustrative, and those skilled in the art will appreciate that various other cage counts and arrangements can be implemented using the same hybrid daughterboard-mainboard concept. This flexibility allows manufacturers and system integrators to tailor the design to accommodate different performance, thermal, and mechanical requirements while still maintaining short trace lengths, robust signal integrity, and high faceplate density.

Referring to FIGS. 4 – 7, note that the central cage structure 14C in the VLC 10C protrudes beyond the plane defined by the outer cage structures 14A and 14B (specifically shown in the side view of FIG. 7). This configuration enables the VLC 10C to be used in network element chassis designs that incorporate angled or “stepped” faceplates. For instance, such faceplate designs are described in commonly assigned U.S. Patent No. 11,516,558, titled “Angled Faceplates for a Network Element,” the contents of which are hereby incorporated by reference in their entirety. Angled or stepped faceplates deviate from a traditional flat design by incorporating multiple plate sections, i.e., often a middle plate flanked by first and second side plates, positioned at an obtuse angle, typically between 130 and 160 degrees, relative to the middle plate. This geometry increases the faceplate’s usable surface area, creating space for additional physical ports, enhanced cooling vents, labeling, and indicators such as Light Emitting Diodes (LEDs). Moreover, “stepping” the middle plate (i.e., having it protrude slightly relative to the side plates) supports the mounting requirements of the centrally located cage structure 14C. This arrangement also provides physical and visual segregation of different port types, such as client ports in the middle plate and high-speed or fabric ports on the angled side plates, thereby improving both cable management and airflow. Ultimately, angled/stepped faceplates help network equipment manufacturers address the growing demand for higher port densities, improved thermal efficiency, reduced power consumption, and lower overall system costs by optimizing PCB routing and offering greater mechanical flexibility.

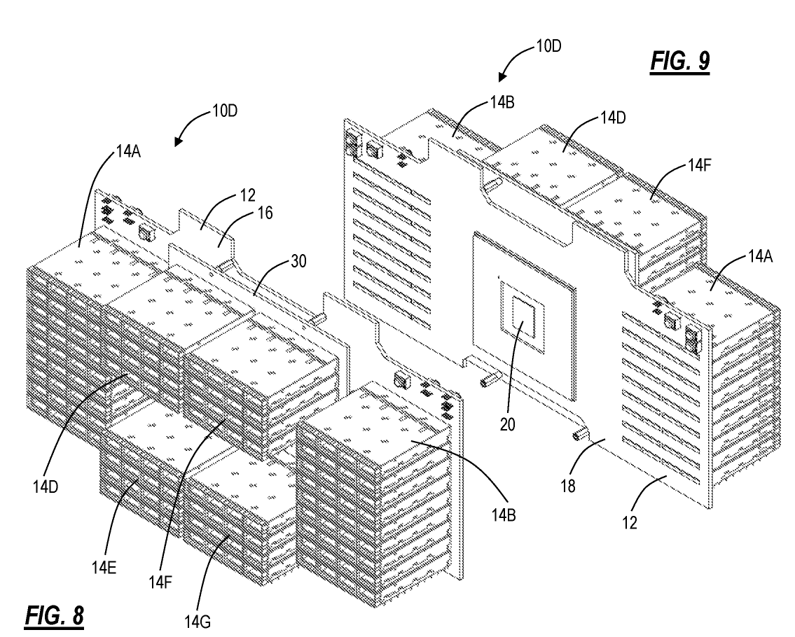

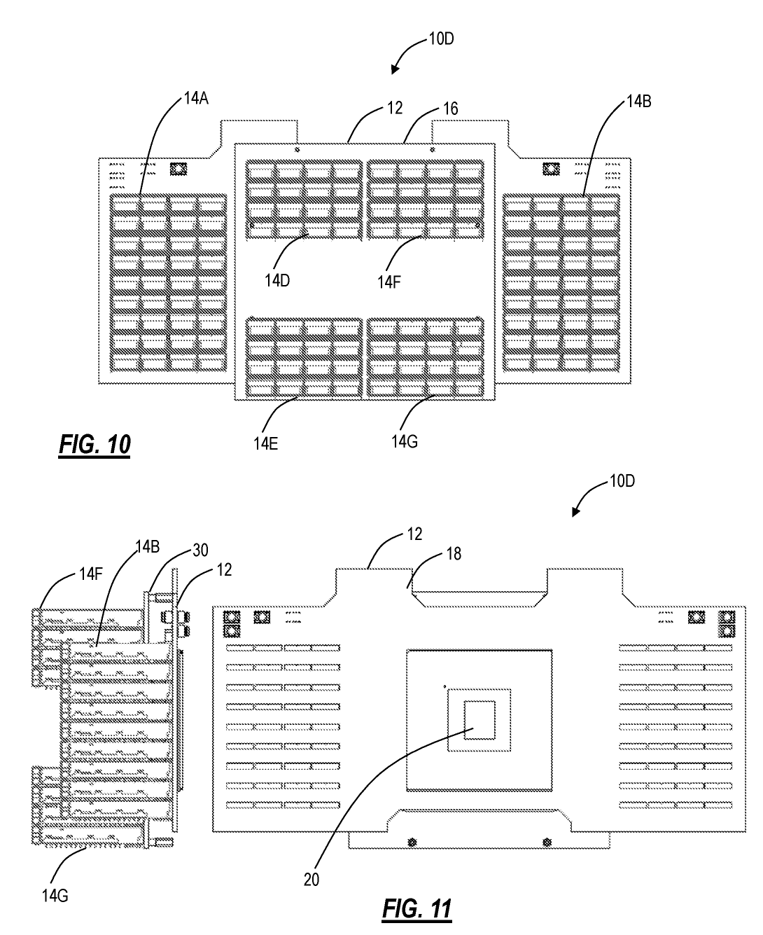

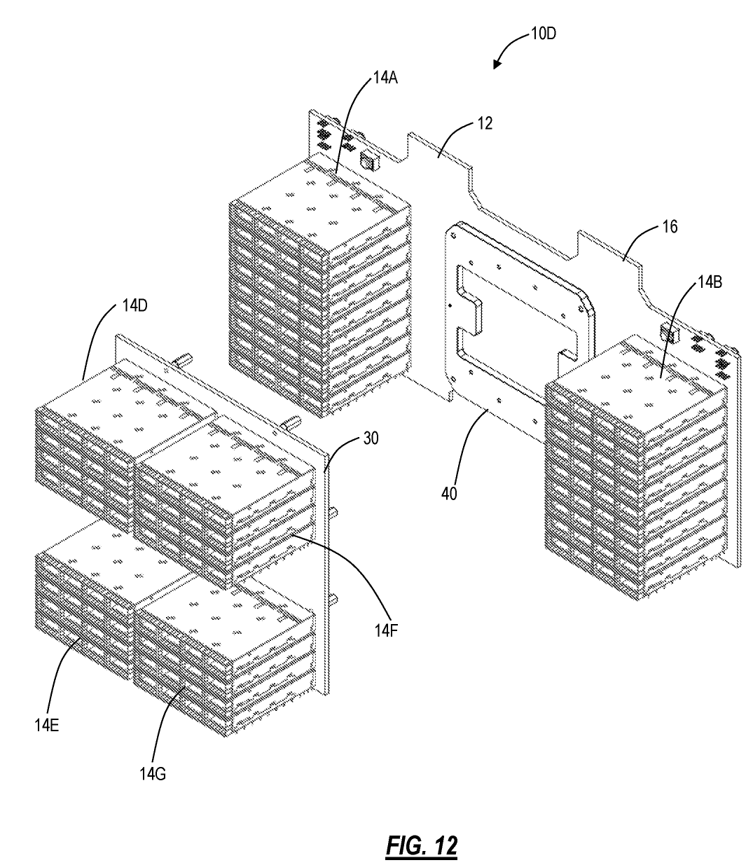

FIGS. 8 – 12 illustrate various views of another example VLC 10D, which represents an alternate configuration relative to VLC 10C and includes central cages in cage structures 14D, 14E, 14F, and 14G . FIG. 8 provides a front-angled perspective of the VLC 10D, highlighting how the central region differs from VLC 10C to accommodate cages and additional mezzanine connector space. FIG. 9 shows a rear-angled perspective of the same assembly, emphasizing the second side 18 of the PCB 12 where the ASIC 20 is mounted, while also revealing the mechanical alignment features for the daughterboard 30. FIG. 10 illustrates a front view of the VLC 10D, detailing the cage openings in cage structures 14A, 14B, 14D, 14E, 14F, 14G. Next, FIG. 11 presents a side view of the VLC 10D along with a rear view of the PCB’s second side 18 and the ASIC 20; this vantage further underscores the difference in vertical stacking heights between the mainboard PCB 12 and the daughterboard 30. Note, in this side view of FIG. 11, the cage structures 14A, 14D, 14E are hidden from view. Finally, FIG. 12 is a front-angled perspective showing the daughterboard 30 disconnected from the PCB 12.

In this example, the outer cage structures 14A and 14B each retain four columns of nine rows, totaling thirty-six cages apiece (seventy-two combined), as in VLC 10C. The central region, however, now includes four distinct cage structures 14D, 14E, 14F, 14G, each providing four columns of four rows, for sixteen cages per structure and sixty-four total in the center. By incorporating these four compact cage structures 14D – 14G on the daughterboard, VLC 10D maintains the benefits of a vertical line card system, such as shorter SerDes trace lengths and robust signal integrity, while allowing for a more modular and flexible layout to accommodate high-density, next-generation optical networking requirements.

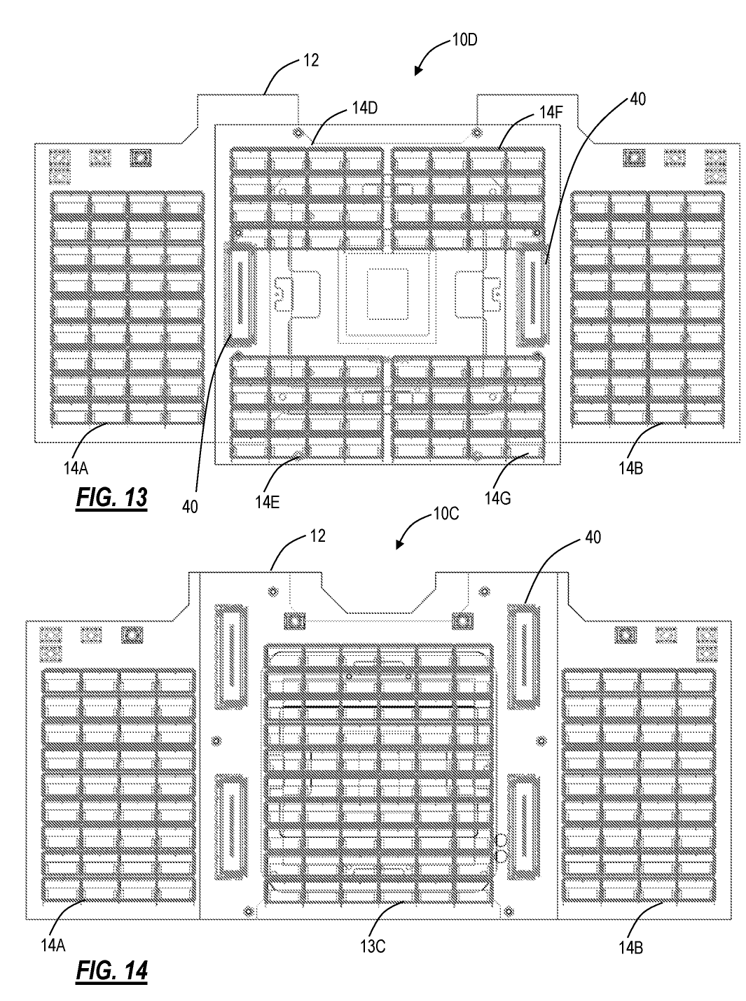

FIGS. 13 and 14 illustrate front views of VLC 10D (FIG. 13) and VLC 10C (FIG. 14), respectively, highlighting how the mezzanine connectors 40 are positioned to electrically and mechanically couple the PCB 12 (mainboard) with the daughterboard 30. In the VLC 10D (FIG. 13), the central region features fewer rows of cages in more cage structures 14D-14G, creating additional space where one or more mezzanine connectors 40 can be conveniently placed. Conversely, the cage layout in the VLC 10C (FIG. 14) requires a more compact arrangement of mezzanine connectors 40 behind or between the cages on the daughterboard. In both designs, the mezzanine connectors 40 are strategically located to minimize high-speed trace lengths between the ASIC 20 on the mainboard 12 and the centrally mounted cage structures on the daughterboard 30, while preserving sufficient area for airflow and heat dissipation. Moreover, these connectors must accommodate significant power delivery and signal integrity requirements, as the ASIC 20 can draw hundreds or even thousands of amperes at multi-terabit data rates. Hence, careful mechanical planning, signal routing, and thermal design all converge in determining the optimal mezzanine connector placement to balance performance, scalability, and reliability in these high-density VLC architectures.

Although VLCs 10C, 10D effectively address the challenges of high port density and reduced SerDes trace lengths, they introduce secondary complications related to power delivery and airflow management. In these designs, the ASIC 20 is a high-powered, high-bandwidth switching device, such as a packet or signal processor capable of handling data at multiple terabit rates, often exceeding 50 Tb/s of total switching capacity. While referred to generically as an ASIC, the device can be any advanced circuit (e.g., field programmable gate array (FPGA), network processor (NP), or custom system on chip (SoC)) requiring substantial power; one representative embodiment demands over 1200 A of current. Consequently, power distribution becomes a significant concern, particularly for the core power pins located near the center of the ASIC 20.

To meet these requirements, design strategies such as busbars or vertical power-delivery solutions must be incorporated to provide stable, low-impedance current paths. Additionally, because the ASIC 20 dissipates considerable heat, airflow from the central cage structures 14D – 14G must be carefully channeled around the daughterboard 30 to reach the ASIC’s 20 heatsink, which is typically oriented perpendicularly to the plane of the chip for optimal thermal transfer. This arrangement demands carefully planned cutouts or flow pathways on both the mainboard PCB 12 and the daughterboard 30, ensuring that cooling air can be delivered in sufficient volume and velocity to maintain safe operating temperatures for the ASIC 20 and surrounding components.

With respect to busbar power delivery to the daughterboard 30, options include remote power generation and end-feed or mid-feed configurations. For remote power generation, employing a busbar for power delivery allows the power generation components, such as driver chips, inductors, and bulk capacitors, to be located remotely from the ASIC 20. This approach can significantly ease thermal management, as the heat-generating power components are no longer constrained to the same PCB area as the high-density SerDes and switching circuitry. It also frees up space near the ASIC 20 for better airflow and additional features, such as mezzanine connectors or daughterboard modules. Depending on the voltage-drop constraints across the ASIC’s power pins, power can be supplied to the busbar from one or both ends. An end-feed configuration may suffice for shorter busbars or lower current draws, while a mid-feed approach distributes power more uniformly along the busbar length, reducing localized power losses and improving voltage regulation at higher currents.

In some embodiments, power generation devices, such as driver chips, inductors, and capacitors, are soldered onto the backside of the main PCB 12 directly opposite critical components. This vertical stacking strategy shortens the conduction path between the power devices and the ASIC’s power pins, thereby mitigating voltage droop and minimizing parasitic losses. Additionally, positioning these power components on the rear side can improve airflow to the ASIC 20 on the front side, as bulky inductors and capacitors no longer compete for limited space around high-speed transceiver cages or heat sinks.

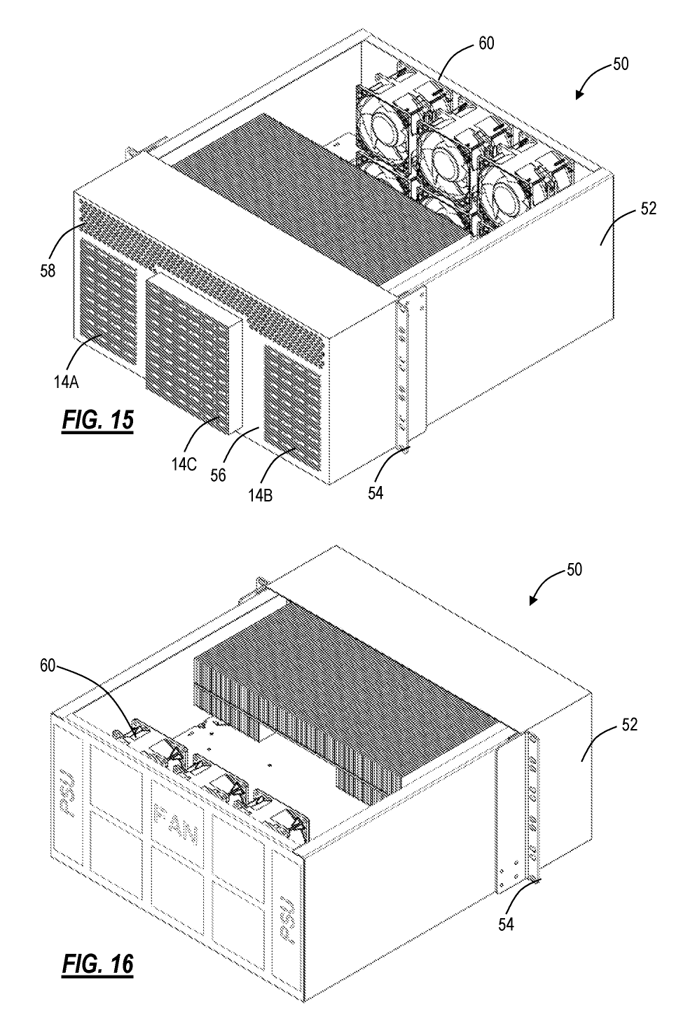

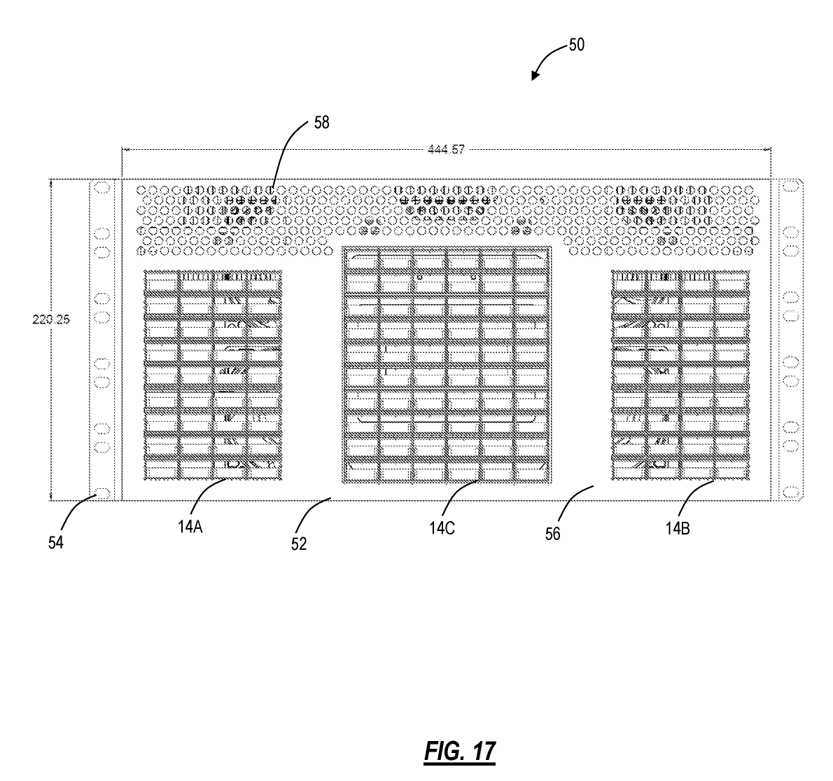

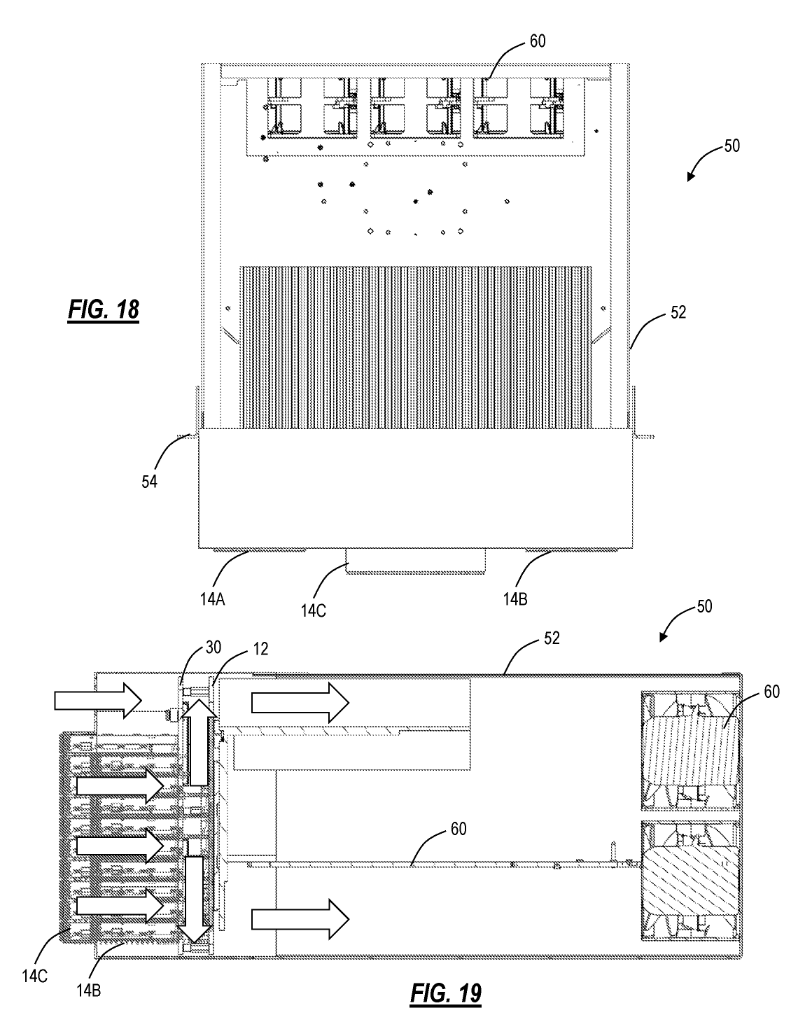

FIGS. 15 – 19 illustrate various views of a network element 50 using the VLC 10C. FIG. 15 provides a front-angled perspective of the network element 50, while FIG. 16 shows a rear-angled perspective of the same assembly. FIG. 16 illustrates a front view of the network element 50 showing the cage openings in the cage structures 14A, 14B, 14C. FIG. 17 is a top view of the network element 50, and FIG. 18 is a side view of the network element 50. The network element 50 includes a housing 52, and FIGS. 15, 16, and 18 illustrate a top side of the housing 52 omitted to show an interior of the network element 50, while FIG. 19 illustrates a side of the housing 52 also omitted.

In an embodiment, the network element 50 is high-density packet switching device, support 100s of OSFPs via the cage structures 14A, 14B, 14C, and tens of terabytes of switching capability via the ASIC 20. The housing 52 can include flanges 54 for mounting the housing 50 to a rack (not shown), such as in a data center. The network element 50 supports front-to-back airflow. A faceplate 56 can include openings 58 for air intake. A rear of the housing 52 can include fan modules 60 for drawing are from the openings 58 for cooling an interior of the network element 50.

In FIG. 19, in addition to the VLC 10C, the network element 50 can include a second main PCB 60. FIG. 19 also illustrates airflow (denoted by large arrows). Air intake is via the cage structures 14A, 14B, 14C and the openings 58. There is also a channel of airflow up and down between the daughterboard 30 and the PCB 12. Finally, air flows based on the fans 60, through the interior of the housing 52.

In this disclosure, including the claims, the phrases “at least one of” or “one or more of” when referring to a list of items mean any combination of those items, including any single item. For example, the expressions “at least one of A, B, or C,” “at least one of A, B, and C,” “one or more of A, B, or C,” and “one or more of A, B, and C” cover the possibilities of: only A, only B, only C, a combination of A and B, A and C, B and C, and the combination of A, B, and C. This can include more or fewer elements than just A, B, and C. Additionally, the terms “comprise,” “comprises,” “comprising,” “include,” “includes,” and “including” are intended to be open-ended and non-limiting. These terms specify essential elements or steps but do not exclude additional elements or steps, even when a claim or series of claims includes more than one of these terms.

Although operations, steps, instructions, blocks, and similar elements (collectively referred to as “steps”) are shown or described in the drawings, descriptions, and claims in a specific order, this does not imply they must be performed in that sequence unless explicitly stated. It also does not imply that all depicted operations are necessary to achieve desirable results. In the drawings, descriptions, and claims, extra steps can occur before, after, simultaneously with, or between any of the illustrated, described, or claimed steps. Multitasking, parallel processing, and other types of concurrent processing are also contemplated. Furthermore, the separation of system components or steps described should not be interpreted as mandatory for all implementations; also, components, steps, elements, etc. can be integrated into a single implementation or distributed across multiple implementations.

While this disclosure has been detailed and illustrated through specific embodiments and examples, it should be understood by those skilled in the art that numerous variations and modifications can perform equivalent functions or achieve comparable results. Such alternative embodiments and variations, even if not explicitly mentioned but that achieve the objectives and adhere to the principles disclosed herein, fall within the spirit and scope of this disclosure. Accordingly, they are envisioned and encompassed by this disclosure and are intended to be protected under the associated claims. In other words, the present disclosure anticipates combinations and permutations of the described elements, operations, steps, methods, processes, algorithms, functions, techniques, modules, circuits, and so on, in any conceivable order or manner—whether collectively, in subsets, or individually—thereby broadening the range of potential embodiments.

What is claimed is:

1. A vertical line card comprising:
a main printed circuit board having at least one high-speed switching integrated circuit disposed thereon;
one or more cage structures mounted on the main printed circuit board, each cage structure comprising a plurality of vertically oriented module cages;
a daughterboard; and
at least one cage structure mounted on the daughterboard, the at least one cage structure comprising a plurality of vertically oriented module cages.

2. The vertical line card of claim 1, wherein signal traces between the high-speed switching integrated circuit and the at least one cage structure are shorter than signal traces between the high-speed switching integrated circuit and the one or more cage structures, thereby reducing insertion loss at high data rates.

3. The vertical line card of claim 1, wherein the high-speed switching integrated circuit comprises a signal processing circuit capable of multiple terabits per second of switching capacity.

4. The vertical line card of claim 1, wherein each of the one or more cage structures and the at least one cage structure is configured to accept one or more of octal small form factor pluggable (OSFP) modules, C-form factor pluggable (CFP) modules, or quad small form factor pluggable (QSFP) modules.

5. The vertical line card of claim 1, further comprising at least one hole or cutout in the main printed circuit board configured to facilitate front-to-back airflow through the vertically oriented module cages.

6. The vertical line card of claim 1, further comprising a power distribution system including at least one busbar or vertical power-delivery structure configured to supply current to the high-speed switching integrated circuit.

7. The vertical line card of claim 1, further comprising one or more mezzanine connectors configured to couple the daughterboard to the main printed circuit board.

8. The vertical line card of claim 7, wherein the daughterboard is positioned between the one or more cage structures which include a first cage structure and a second cage structure, and the one or more mezzanine connectors are located to optimize signal integrity and airflow to a heatsink associated with the high-speed switching integrated circuit.

9. The vertical line card of claim 7, wherein the at least one cage structure protrudes outward from a plane defined by the one or more cage structures to accommodate higher faceplate density within a limited chassis height.

10. The vertical line card of claim 1, wherein the at least one cage structure is a single structure having more cages than the one or more cage structures.

11. The vertical line card of claim 1, wherein the at least one cage structure includes a plurality of cage structures, where the plurality of cage structures are each on the daughterboard.

12. A network element comprising:
a housing; and
a vertical line card disposed within the housing, the vertical line card comprising
a main printed circuit board having at least one high-speed switching integrated circuit disposed thereon;
one or more cage structures mounted on the main printed circuit board, each cage structure comprising a plurality of vertically oriented module cages;
a daughterboard; and
at least one cage structure mounted on the daughterboard, the at least one structure comprising a plurality of vertically oriented module cages.

13. The network element of claim 12, wherein signal traces between the high-speed switching integrated circuit and the at least one cage structure are shorter than signal traces between the high-speed switching integrated circuit and the one or more structures, thereby reducing insertion loss at high data rates.

14. The network element of claim 12, wherein the high-speed switching integrated circuit comprises a signal processing circuit capable of multiple terabits per second of switching capacity.

15. The network element of claim 12, wherein each of the one or more cage structures and the at least one cage structure is configured to accept one or more of octal small form factor pluggable (OSFP) modules, C-form factor pluggable (CFP) modules, or quad small form factor pluggable (QSFP) modules.

16. The network element of claim 12, further comprising a cooling system arranged to provide front-to-back airflow through the housing, wherein the vertical line card includes at least one hole or cutout in the main printed circuit board configured to facilitate front-to-back airflow through the vertically oriented module cages.

17. The network element of claim 12, further comprising a power supply arranged to provide current to the vertical line card, wherein the vertical line card includes at least one busbar or vertical power-delivery structure configured to supply current to the high-speed switching integrated circuit.

18. The network element of claim 12, wherein the vertical line card further comprises one or more mezzanine connectors that couple the daughterboard to the main printed circuit board.

19. The network element of claim 12, wherein the at least one cage structure is a single structure having more cages than the one or more cage structures.

20. The network element of claim 12, wherein the at least one cage structure includes a plurality of cage structures, where the plurality of cage structures are each on the daughterboard.
